(19) United States
(12) Patent Application Publication
(10) Pub. No.: US 2022/0412590 A1
(43) Pub. Date: Dec. 29, 2022

(54) AIR CONDITIONING UNIT WITH FAN PERFORMANCE MONITORING BY A TEMPERATURE SENSOR

(71) Applicant: Haier US Appliance Solutions, Inc., Wilmington, DE (US)

(72) Inventors: Timothy Scott Shaffer, La Grange, KY (US); Joseph Robert Tobbe, Louisville, KY (US)

(21) Appl. No.: 17/359,876

(22) Filed: Jun. 28, 2021

(51) Int. Cl. F24F 11/32; F24F 11/52

(52) U.S. Cl. CPC F24F 11/32; F24F 11/52; F24F 2140/00

(57) ABSTRACT

An air conditioning appliance includes a heat exchanger disposed within a housing. A compressor is in fluid communication with the heat exchanger. The compressor is operable to circulate refrigerant through the heat exchanger. A fan is disposed within the housing. The fan is operable to flow air over the heat exchanger. A circuit board is disposed within the housing, and a heat sink is mounted to the circuit board. The heat sink positioned such that the fan flows air over the heat sink during operation of the fan. A temperature sensor is disposed at one or both of the heat sink and the circuit board. A controller is in operative communication with the temperature sensor. The controller is configured to receive a signal from the temperature sensor corresponding to a temperature measurement and to activate an alert at least partially in response to the temperature measurement exceeding a temperature limit.

### FIELD OF THE INVENTION

The present subject matter relates generally to air conditioning units.

### BACKGROUND OF THE INVENTION

Air conditioners or air conditioner units are conventionally used to adjust the temperature within structures such as dwellings and office buildings. One-unit type room air conditioners, such as single package vertical units (SPVU) or package terminal air conditioners (PTAC), are frequently used to adjust the temperature in a single room or group of rooms of a structure. Such units may be especially useful in the context of a hotel or office building where users desire control of the temperature within a specific room of a larger building structure. A typical one-unit type air conditioner or air conditioning appliance includes an indoor portion and an outdoor portion. The indoor portion generally communicates (e.g., exchanges air) with the area within a building, and the outdoor portion generally communicates (e.g., exchanges air) with the area outside a building. Generally, a fan may be operable to rotate to motivate air through the indoor portion, and another fan may be operable to rotate to motivate air through the outdoor portion. One or more control boards are typically provided to direct the operation of various elements of the particular air conditioner unit.

In practice, various issues can arise with conventional units. Sensors are frequently used to measure unit operating parameters. However, component failures make operation difficult. For example, a poorly performing fan can negatively affect operation of an air conditioner unit.

### BRIEF DESCRIPTION OF THE INVENTION

Example aspects of the present subject matter assist with detecting a poorly performing fan within an air conditioner unit. For example, a temperature of a heat sink positioned within air flow of the fan may be measured with a temperature sensor. Tracking the heat sink temperature measurements, e.g., as a function of fan speed and/or ambient temperature, may assist with detecting poor fan performance. Thus, a user may be alerted to the need for servicing fan. Aspects and advantages of the invention will be set forth in part in the following description, or may be obvious from the description, or may be learned through practice of the invention.

In one exemplary aspect of the present disclosure, an air conditioning appliance includes a housing. A heat exchanger is disposed within the housing. A compressor is in fluid communication with the heat exchanger. The compressor is operable to circulate refrigerant through the heat exchanger. A fan is disposed within the housing. The fan is operable to flow air over the heat exchanger. A circuit board is disposed within the housing. A heat sink is mounted to the circuit board. The heat sink is positioned such that the fan flows air over the heat sink during operation of the fan. A temperature sensor is disposed at one or both of the heat sink and the circuit board. A controller is in operative communication with the temperature sensor. The controller is configured to receive a signal from the temperature sensor corresponding to a temperature measurement and to activate an alert at least partially in response to the temperature measurement exceeding a temperature limit.

In another exemplary aspect of the present disclosure, an air conditioning appliance including a housing. A condenser disposed within the housing. A compressor is in fluid communication with the condenser. The compressor is operable to circulate refrigerant through the condenser. A fan is disposed within the housing. The fan is operable to flow air over the condenser. An inverter board is disposed within the housing. A heat sink is mounted to the inverter board. The heat sink is positioned such that the fan flows air over the condenser during operation of the fan. A temperature sensor is disposed at one or both of the inverter board and the heat sink. A controller is in operative communication with the temperature sensor. The controller is configured to receive a signal from the temperature sensor corresponding to a temperature measurement and to activate an alert at least partially in response to the temperature measurement exceeding a temperature limit.

In another exemplary aspect of the present disclosure, a method for operating an air conditioning appliance is provided. The air conditioning appliance includes a fan disposed within a housing and a heat sink mounted to a circuit board. The fan is operable to flow air over a heat exchanger. The heat sink is positioned such that the fan flows air over the heat sink during operation of the fan. The method includes receiving a signal from a temperature sensor disposed proximate the heat sink and activating an alert at least partially in response to the signal from the temperature sensor corresponds to a temperature measurement that exceeds a temperature limit.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a perspective view of an air conditioning appliance according to exemplary embodiments of the present disclosure.

FIG. 2 provides another perspective view of the exemplary air conditioner unit of FIG. 1.

FIG. 3 provides partial, perspective view of the exemplary air conditioner unit of FIG. 1 and shows a heat sink of the exemplary air conditioner unit.

FIG. 4 provides a perspective view of a circuit board of the exemplary air conditioner unit of FIG. 1.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents. As used herein, the terms “includes” and “including” are intended to be inclusive in a manner similar to the term “comprising.” Similarly, the term “or” is generally intended to be inclusive (i.e., “A or B” is intended to mean “A or B or both”). The terms “upstream” and “downstream” refer to the relative flow direction with respect to fluid flow in a fluid pathway. For example, “upstream” refers to the flow direction from which the fluid flows, and “downstream” refers to the flow direction to which the fluid flows. Furthermore, as used herein, terms of approximation, such as “approximately,” “substantially,” or “about,” refer to being within a ten percent margin of error.

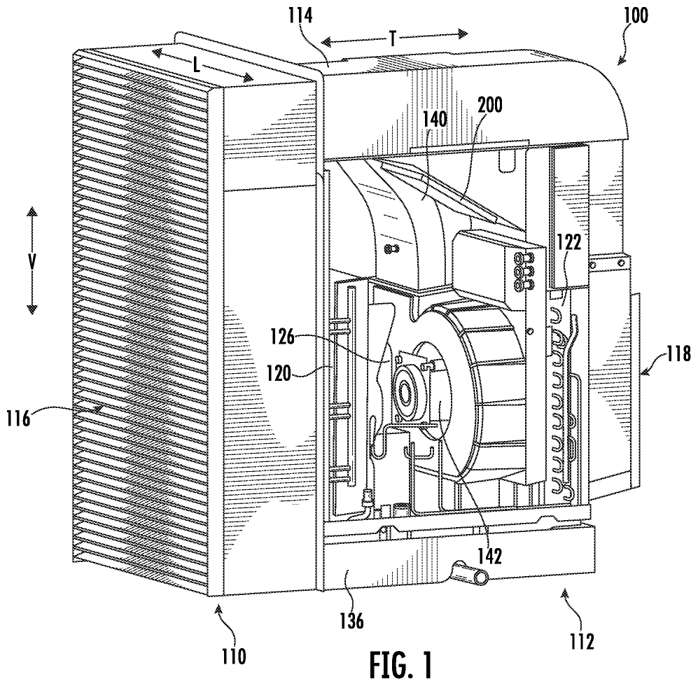

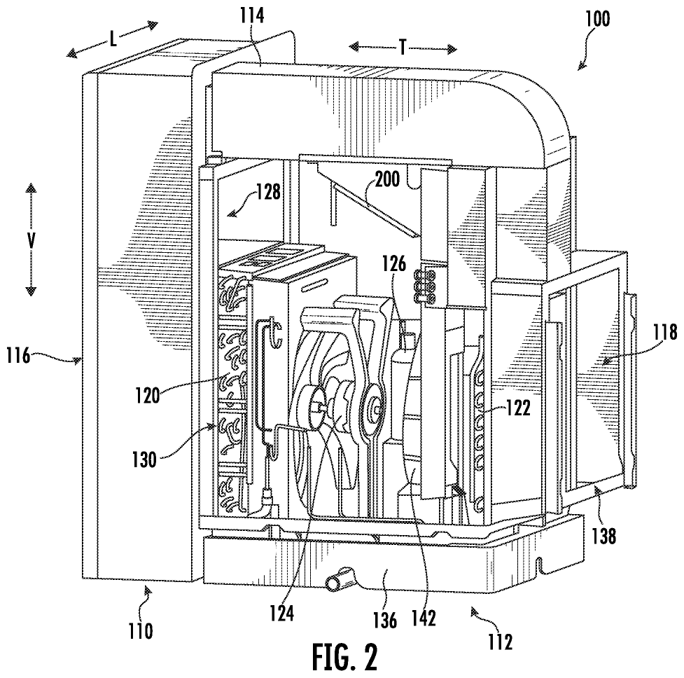

Turning now to the figures, FIGS. 1 through 3 illustrate an exemplary air conditioning appliance (e.g., air conditioner 100). As shown, air conditioner 100 may be provided as a one-unit type air conditioner 100, such as a single-package vertical unit. Air conditioner 100 includes a package housing 114 supporting an indoor portion 112 and an outdoor portion 110. Generally, air conditioner 100 defines a vertical direction V, lateral direction L, and transverse direction T that are mutually perpendicular, e.g., such that an orthogonal coordinate system is generally defined.

In some example embodiments, housing 114 contains various components of the air conditioner 100. Housing 114 may include, for example, a rear opening 116 (e.g., with or without a grill or grate thereacross) and a front opening 118 (e.g., with or without a grill or grate thereacross) may be spaced apart from each other along the transverse direction T. The rear opening 116 may be part of the outdoor portion 110, while the front opening 118 is part of the indoor portion 112. Components of the outdoor portion 110, such as an outdoor heat exchanger 120, outdoor fan 124, and compressor 126 may be enclosed within housing 114 between front opening 118 and rear opening 116. In certain example embodiments, one or more components of outdoor portion 110 are mounted on a basepan 136, as shown.

During certain operations, air may be drawn to outdoor portion 110 through rear opening 116. Specifically, an outdoor inlet 128 defined through housing 114 may receive outdoor air motivated by outdoor fan 124. Within housing 114, the received outdoor air may be motivated through or across outdoor fan 124. Moreover, at least a portion of the outdoor air may be motivated through or across outdoor heat exchanger 120 before exiting the rear opening 116 at an outdoor outlet 130. It is noted that although outdoor inlet 128 is illustrated as being defined above outdoor outlet 130, alternative example embodiments may reverse this relative orientation (e.g., such that outdoor inlet 128 is defined below outdoor outlet 130) or provide outdoor inlet 128 beside outdoor outlet 130 in a side-by-side orientation, or another suitable discrete orientation.

As shown, indoor portion 112 may include an indoor heat exchanger 122, a blower fan 142, and a heating unit (not shown). These components may, for example, be housed behind the front opening 118. A bulkhead 134 may generally support or house various other components or portions thereof of the indoor portion 112, such as the blower fan 142. Bulkhead 134 may generally separate and define the indoor portion 112 and outdoor portion 110 within housing 114. Additionally or alternatively, bulkhead 134 or indoor heat exchanger 122 may be mounted on basepan 136 (e.g., at a higher vertical position than outdoor heat exchanger 120).

During certain operations, air may be drawn to indoor portion 112 through front opening 118. Specifically, an indoor inlet 138 defined through housing 114 may receive indoor air motivated by blower fan 142. At least a portion of the indoor air may be motivated through or across indoor heat exchanger 122 (e.g., before passing to bulkhead 134). From blower fan 142, indoor air may be motivated (e.g., across the heating unit, which may include one or more electric or resistive heating elements) and returned to an indoor area of a room through an indoor outlet 140 defined through housing 114 (e.g., above indoor inlet 138 along the vertical direction V). Optionally, one or more conduits (not pictured) may be mounted on or downstream from indoor outlet 140 to further guide air from air conditioner 100. It is noted that although indoor outlet 140 is illustrated as generally directing air upward, it is understood that indoor outlet 140 may be defined in alternative example embodiments to direct air in any other suitable direction.

Outdoor and indoor heat exchanger 120, 122 may be components of a thermodynamic assembly (i.e., sealed system), which may be operated as a refrigeration assembly (and thus perform a refrigeration cycle) or, in the case of the heat pump unit embodiment, a heat pump (and thus perform a heat pump cycle). Thus, as is understood, exemplary heat pump unit embodiments may be selectively operated perform a refrigeration cycle at certain instances (e.g., while in a cooling mode) and a heat pump cycle at other instances (e.g., while in a heating mode). By contrast, exemplary A/C exclusive unit embodiments may be unable to perform a heat pump cycle (e.g., while in the heating mode), but still perform a refrigeration cycle (e.g., while in a cooling mode).

The sealed system may, for example, further include compressor 126 (e.g., mounted on basepan 136) and an expansion device (e.g., expansion valve or capillary tube—not shown), both of which may be in fluid communication with the heat exchangers 120, 122 to flow refrigerant therethrough, as is generally understood. The outdoor and indoor heat exchanger 120, 122 may each include coils, as illustrated, through which a refrigerant may flow for heat exchange purposes, as is generally understood.

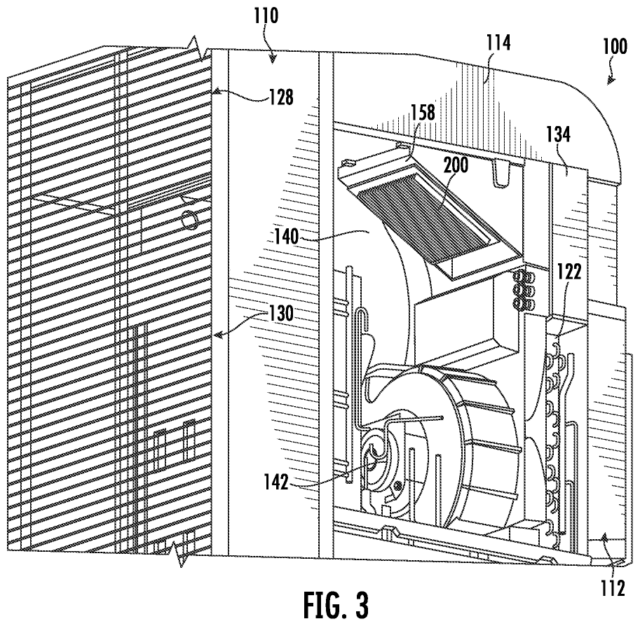

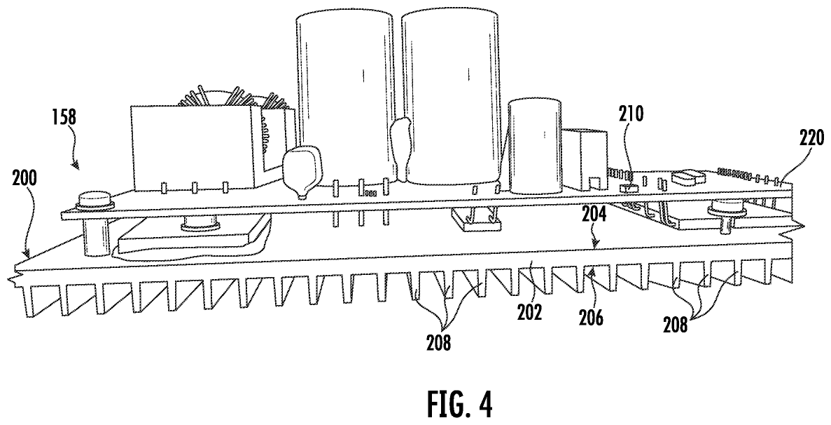

The operation of air conditioner 100 including compressor 126 (and thus the sealed system generally), blower fan 142, outdoor fan 124, the heating unit, and other suitable components may be controlled by a control board or controller 158 (FIGS. 3 and 4). Controller 158 may be in communication (via for example a suitable wired or wireless connection) to such components of the air conditioner 100. By way of example, the controller 158 may include a memory and one or more processing devices such as microprocessors, CPUs or the like, such as general or special purpose microprocessors operable to execute programming instructions or micro-control code associated with operation of air conditioner 100. The memory may be a separate component from the processor or may be included onboard within the processor. The memory may represent random access memory such as DRAM, or read only memory such as ROM or FLASH.

Air conditioner 100 may additionally include a control panel and one or more user inputs, which may be included in control panel. The user inputs may be in communication with the controller 158. A user of the air conditioner 100 may interact with the user inputs to operate the air conditioner 100, and user commands may be transmitted between the user inputs and controller 158 to facilitate operation of the air conditioner 100 based on such user commands. A display may additionally be provided in the control panel, and may be in communication with the controller 158. The display may, for example be a touchscreen or other text-readable display screen, or alternatively may simply be a light that can be activated and deactivated as required to provide an indication of, for example, an event or setting for the air conditioner 100.

As shown in FIG. 4, air conditioner 100 includes a circuit board 220. In the example embodiment shown in FIG. 4, circuit board 220 is integrated with controller 158. Thus, circuit board 220 may form at least a portion of controller 158. However, it will be understood that controller 158 may be separately formed from circuit board 220 in alternative example embodiments. For example, controller 158 may be formed with another circuit board disposed at another location within air conditioner 100. Circuit board 220 may be in communication with controller 158 in such example embodiments, e.g., via a wiring harness.

Circuit board 220 may include various components for regulating operation of components within air conditioner 100. For example, circuit board 220 may include one or more MOSFETs (metal-oxide-semiconductor field-effect transistors), one or more bridge rectifiers, one or more IPMs (intelligent power modules), one or more electrolytic capacitors, one or more filter inductors, etc. Circuit board 220 may be configured for regulating operation of compressor 126. For example, circuit board 220 may be configured as an inverter board to convert direct current (DC) to alternating current (AC) for regulating an operating speed of compressor 126. The electrical components on circuit board 220 may mechanically degrade at temperatures greater than a temperature limit. For instance, certain electrical components, such as MOSFETs, may begin to mechanically degrade at temperatures greater than one hundred and twenty-five degrees Celsius (125° C.).

A heat sink 200 is mounted to circuit board 220. As shown in FIGS. 1-3, heat sink 200 is positioned such that outdoor fan 124 flows air over or across heat sink 200 during operation of outdoor fan 124. For example, heat sink 200 may be mounted on housing 114 within outdoor portion 110 of housing 114, e.g., between outdoor inlet 128 and outdoor outlet 130. Thus, as outdoor fan 124 urges air through outdoor portion 110 from outdoor inlet 128 to outdoor outlet 130, the air may flow across heat sink 200.

Heat sink 200 may include a plate 202 and a plurality of projections 208. Plate 202 may be mounted to circuit board 220 (e.g., with fasteners) at a first side 204 of plate 202. Projections 208 may extend outwardly from plate at a second side 206 of plate 202. Heat sink 200 may be formed from a heat conductive material, such as aluminum. For example, plate 202 and projections 208 may be formed from a single, continuous piece of aluminum. Temperature sensor 210 may be disposed at or proximate first side 204 of plate 202.

Heat sink 200 may facilitate rejection of heat from circuit board 220 to the air flowing due to outdoor fan 124. For example, projections 208 may extend into an air flow path within housing 114 created by outdoor fan 124. During operation of circuit board 220, the temperature of electrical components on circuit board 220 may increase. To avoid overheating, the electrical components on circuit board 220 may reject heat to heat sink 200, e.g., primarily or predominately via conductive heat transfer. In turn, heat sink 200 may reject the heat from circuit board 220 to the air flowing due to outdoor fan 124, e.g., primarily or predominately via convective heat transfer.

A temperature sensor 210 is disposed at one or both of heat sink 200 and circuit board 220. For example, as shown in FIG. 1, temperature sensor 210 may be mounted on circuit board 220. In particular, temperature sensor 210 may be a thermistor mounted on circuit board 220 in certain example embodiments. In alternative example embodiments, temperature sensor 210 may be mounted on heat sink 200 or between heat sink 200 and circuit board 220. Temperature sensor 210 may be configured to measure one or both of the temperature of heat sink 200 and circuit board 220. Thus, a signal from temperature sensor 210 may correspond to the temperature of one or both of heat sink 200 and circuit board 220.

As noted above, heat sink 200 may facilitate rejection of heat from circuit board 220 to the air flowing due to outdoor fan 124 to avoid overheating of electrical components on circuit board 220. The cooling of circuit board 220 relies upon proper operation of outdoor fan 124. When outdoor fan 124 is not operating properly, the cooling of circuit board 220 is interrupted. For instance, if a motor of outdoor fan 124 is malfunctioning such that outdoor fan 124 is not drawing sufficient air for cooling circuit board 220 and/or if one or both of outdoor inlet 128 and outdoor outlet 130 is blocked such that outdoor fan 124 cannot draw sufficient air for cooling circuit board 220, the temperature measurements from temperature sensor 210 may increase over time. Thus, as described in greater detail below, the present subject matter may monitor operation of outdoor fan 124 using temperature sensor 210.

Controller 158 may be in operative communication with temperature sensor 210. Thus, controller 158 may receive one or more signals from temperature sensor 210, and the signal(s) from temperature sensor 210 may correspond to a temperature measurement. Controller 158 may receive the signal(s) from temperature sensor 210 via wired or wireless connection. For example, as noted as noted above, temperature sensor 210 may be integrated within one or both of controller 158 and circuit board 220. Thus, leads within controller 158 and/or circuit board 220 may provide the signal communication with temperature sensor 210.

Controller 158 may also be configured to activate an alert at least partially in response to the temperature measurement from temperature sensor 210 exceeding a temperature limit. As noted above, temperature sensor 210 may measure one or both of the temperature of heat sink 200 and circuit board 220. Thus, when controller 158 receives the signal(s) from temperature sensor 210, controller 158 may determine when the temperature of one or both of heat sink 200 and circuit board 220 exceeds the temperature limit. Based at least in part on the temperature measurement from temperature sensor 210 exceeding the temperature limit, controller 158 may activate the alert in order to inform a user of air conditioner 100 that outdoor fan 124 may not be operating properly.

The temperature measurements from temperature sensor 210 may increase over time when the motor of outdoor fan 124 is malfunctioning such that outdoor fan 124 is not drawing sufficient air for cooling circuit board 220 and/or when one or both of outdoor inlet 128 and outdoor outlet 130 is blocked such that outdoor fan 124 cannot draw sufficient air for cooling circuit board 220. Thus, controller 158 may monitor operation of outdoor fan 124 (e.g., at least the ability of outdoor fan 124 to cool heat sink 200 and/or circuit board 220) via temperature measurements. The alert may inform the user to schedule maintenance for air conditioner 100, to check outdoor inlet 128 and/or outdoor outlet 130 for blockages, etc. The alert may be a message on the control panel of air conditioner 100, an audible alert, a warning light, a text message, an email, etc. Controller 158 may also deactivate compressor 126 at least partially in response to the temperature measurement from temperature sensor 210 exceeding the temperature limit. Conversely, controller 158 may continue to operate air conditioner 100 in a normal manner when the temperature measurement from temperature sensor 210 does not exceed the temperature limit.

The temperature limit may be selected to avoid damage to electrical components on circuit board 220. For example, the temperature limit may be no less than seventy degrees Celsius (70° C.) and no greater than one hundred degrees Celsius (100° C.). As another example, the temperature limit may be no less than seventy degrees Celsius (70° C.) and no greater than eighty degrees Celsius (80° C.). As a particular example, the temperature limit may be about seventy-five degrees Celsius (75° C.). The above-described temperature limits may assist with avoiding damage to electrical components of circuit board 220, such as MOSFETs, due to overheating. When the temperature measurement from temperature sensor 210 does not exceed the temperature limit, air conditioner 100 may operate normally due to outdoor fan 124 operating in a manner that sufficiently cools heat sink 200 and/or circuit board 220.

Controller 158 may be further configured to activate the alert in response to the temperature measurement from temperature sensor 210 exceeding the temperature limit and an ambient temperature being greater than a threshold temperature. Thus, controller 158 may also utilize the ambient outdoor temperature to determine when to activate the alert. When the ambient temperature is relatively low, the cooling of heat sink 200 and/or circuit board 220 should be ensured when outdoor fan 124 is operating properly and when outdoor inlet 128 and outdoor outlet 130 are not blocked. Conversely, at relatively high ambient temperatures, the cooling of heat sink 200 and/or circuit board 220 may be significantly reduced such that the temperature limit may be reached even when outdoor fan 124 is operating properly and when outdoor inlet 128 and outdoor outlet 130 are not blocked. Controller 158 may be in operative communication with another temperature sensor (not shown) that is configured to measure the ambient temperature.

The threshold temperature may be selected to avoid unnecessary alerts and/or ensure that the temperature limit is applicable. For example, the threshold temperature may be no less than thirty-four degrees Celsius (34° C.) and no greater than thirty-eight degrees Celsius (38° C.). As a particular example, the threshold temperature may be about thirty-five and a half degrees Celsius (35.5° C.).

As may be seen from the above, an aluminum heat sink may be assembled to inverter board componentry, which generates significant heat during operation of an air conditioner. The inverter board and heat sink may be disposed within the air conditioner such that heat sink is exposed to outdoor-side airflow. Thus, the heat sink may be in a state of forced convection during operation of a compressor, as the outdoor fan always run alongside the compressor. A controller monitors a change in heat sink temperature over time as the compressor and outdoor fan operate. Compressor operation can be terminated when cooling of the heat sink is outside of a predetermined range. Poor performance of the outdoor fan can lead to poor reliability and inefficient operation of the air conditioner. Tracking variations of the heat sink temperature, e.g., as a function of fan speed and outdoor ambient temperature, can advantageously assist with identifying the onset of poor outdoor fan performance.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An air conditioning appliance, comprising:
a housing;
a heat exchanger disposed within the housing;
a compressor in fluid communication with the heat exchanger, the compressor operable to circulate refrigerant through the heat exchanger;
a fan disposed within the housing, the fan operable to flow air over the heat exchanger;
a circuit board disposed within the housing;
a heat sink mounted to the circuit board, the heat sink positioned such that the fan flows air over the heat sink during operation of the fan;
a temperature sensor disposed at one or both of the heat sink and the circuit board; and
a controller in operative communication with the temperature sensor, the controller configured to receive a signal from the temperature sensor corresponding to a temperature measurement and to activate an alert at least partially in response to the temperature measurement exceeding a temperature limit.

2. The air conditioning appliance of claim 1, wherein the heat sink comprises a plate and a plurality of projections, the plate mounted to the circuit board at a first side of the plate, the plurality of projections extending outwardly from the plate at a second side of the plate.

3. The air conditioning appliance of claim 2, wherein the temperature sensor is disposed proximate the first side of the plate.

4. The air conditioning appliance of claim 2, wherein the plurality of projections extend into an air flow path within the housing.

5. The air conditioning appliance of claim 1, wherein the temperature sensor is disposed on the circuit board.

6. The air conditioning appliance of claim 1, wherein the controller is configured to activate the alert when the temperature measurement exceeds the temperature limit and an ambient temperature is greater than a threshold temperature.

7. The air conditioning appliance of claim 1, wherein the alert comprises a fan performance alert.

8. The air conditioning appliance of claim 1, wherein the heat exchanger is a condenser.

9. The air conditioning appliance of claim 1, wherein the circuit board comprises an inverter.

10. An air conditioning appliance, comprising:
a housing;
a condenser disposed within the housing;
a compressor in fluid communication with the condenser, the compressor operable to circulate refrigerant through the condenser;
a fan disposed within the housing, the fan operable to flow air over the condenser;
an inverter board disposed within the housing;
a heat sink mounted to the inverter board, the heat sink positioned such that the fan flows air over the condenser during operation of the fan;
a temperature sensor disposed at one or both of the inverter board and the heat sink; and
a controller in operative communication with the temperature sensor, the controller configured to receive a signal from the temperature sensor corresponding to a temperature measurement and to activate an alert at least partially in response to the temperature measurement exceeding a temperature limit.

11. The air conditioning appliance of claim 10, wherein the heat sink comprises a plate and a plurality of projections, the plate mounted to the inverter board at a first side of the plate, the plurality of projections extending outwardly from the plate at a second side of the plate.

12. The air conditioning appliance of claim 11, wherein the temperature sensor is disposed proximate the first side of the plate.

13. The air conditioning appliance of claim 11, wherein the plurality of projections extend into an air flow path within the housing.

14. The air conditioning appliance of claim 10, wherein the temperature sensor is disposed on the inverter board.

15. The air conditioning appliance of claim 10, wherein the controller is configured to activate the alert when the temperature measurement exceeds the temperature limit and an ambient temperature is greater than a threshold temperature.

16. The air conditioning appliance of claim 10, wherein the alert comprises a fan performance alert.

17. A method for operating an air conditioning appliance, the air conditioning appliance comprising a fan disposed within a housing and a heat sink mounted to a circuit board, the fan operable to flow air over a heat exchanger, the heat sink positioned such that the fan flows air over the heat sink during operation of the fan, the method comprising:
receiving a signal from a temperature sensor disposed proximate the heat sink; and
activating an alert at least partially in response to the signal from the temperature sensor corresponds to a temperature measurement that exceeds a temperature limit.

18. The method of claim 17, wherein activating the alert comprises activating the alert when the signal from the temperature sensor corresponds to the temperature measurement that exceeds the temperature limit and an ambient temperature is greater than a threshold temperature.

19. The method of claim 18, wherein the alert comprises a fan performance alert.
